(19) United States
(12) Patent Application Publication
(10) Pub. No.: US 2007/0108437 A1
(43) Pub. Date: May 17, 2007

(54) Method of fabrication of high temperature superconductors based on new mechanism of electron-electron interaction

(76) Inventor: Avto Tavkhelidze, Tbilisi (GE)

Correspondence Address: Borealis Technical Limited, 23545 NW Skyline Blvd, North Plains, OR, 97133-9204, US

(21) Appl. No.: 11/509,111

(22) Filed: Aug. 23, 2006

Related U.S. Application Data
(63) Continuation-in-part of application No. 10/991,257, filed on Nov. 16, 2004.
Application No. 10/991,257 is a continuation-in-part of application No. 10/508,914, filed on Sep. 22, 2004, now Pat. No. 7,074,498.
(63) Continuation-in-part of application No. 10/760,697, filed on Jan. 19, 2004, now Pat. No. 7,166,786.
Application No. 10/760,697 is a division of application No. 09/634,615, filed on Aug. 5, 2000, now Pat. No. 6,680,214.
Application No. 10/760,697 is a continuation of application No. 09/093,652, filed on Jun. 8, 1998, now abandoned.
(60) Provisional application No. 60/366,563, filed on Mar. 22, 2002.
(60) Provisional application No. 60/366,564, filed on Mar. 22, 2002.
(60) Provisional application No. 60/373,508, filed on Apr. 17, 2002.
(60) Provisional application No. 60/149,805, filed on Aug. 18, 1999.

(30) Foreign Application Priority Data
Aug. 23, 2005 (GB) GB0517167.3

(51) Int. Cl. H01L 39/22; H01L 29/06; H01L 29/08

(52) U.S. Cl. 257/36

(57) ABSTRACT

The present invention is a superconducting tunnel junction comprising two thin films characterized in that the thin films have an indented surface facing each other and are separated by an insulator layer. Typically, the depth of the indents is in the range of 5 to 10 nm, the width of the indents is in the range of 50 to 200 nm, the thickness of the insulator layer is in the range of 1 to 3 nm, and the thickness of the films is less than electron mean free path of a material comprising said films, and is typically in the range of 50 to 100 nm. Preferably the films are single crystal films or amorphous films.

### CROSS-REFERENCE TO RELATED APPLICATIONS

This application claims the benefit of U.K. Provisional Patent App. No. GB0517167.3, filed Aug. 23, 2005. This application is a Continuation-in-Part of U.S. patent application Ser. No. 10/991,257, filed Nov. 16, 2004, which is a Continuation-in-Part application of application Ser. No. 10/508,914 filed Sep. 22, 2004, now U.S. Pat. No. 7,074,498, which is a U.S. national stage application of International Application PCT/US03/08907, filed Mar. 24, 2003, which international application was published on Oct. 9, 2003, as International Publication WO03083177 in the English language. The International Application claims the benefit of U.S. Provisional Application No. 60/366,563, filed Mar. 22, 2002, U.S. Provisional Application No. 60/366,564, filed Mar. 22, 2002, and U.S. Provisional Application No. 60/373,508, filed Apr. 17, 2002. This application is also a Continuation-in-Part application of application Ser. No. 10/760,697 filed Jan. 19, 2004 which is a Divisional application of application Ser. No. 09/634,615, filed Aug. 5, 2000, now U.S. Pat. No. 6,680,214, which claims the benefit of U.S. Provisional Application No. 60/149,805, filed on Aug. 18, 1999, and is a Continuation application of application Ser. No. 09/093,652, filed Jun. 8, 1998, now abandoned, and is related to application Ser. No. 09/020,654, filed Feb. 9, 1998, now U.S. Pat. No. 6,281,514. The above-mentioned patent applications are assigned to the assignee of the present application and are herein incorporated in their entirety by reference.

### BACKGROUND OF THE INVENTION

The present invention relates to high temperature superconductors.

High Temperature Superconductivity was discovered almost 20 years ago, in ceramics of the type YBa₂Cu₃O₇₋ₓ. Since then, superconducting transition temperatures as high as 120-130 K have been obtained in several different types of ceramics. Experiments show that in high temperature superconductors (HTS), as in traditional superconductors such as Pb and Nb, the superconducting current is carried by Cooper pairs [Leon N. Cooper “Bound Electron Pairs in Degenerate Fermi Gas” Phys. Rev., v.104, p. 1189, (1956)]. However, HTS' high temperatures of superconductive transition and extremely low value of order parameters (the distance at which the wave function of the Bose condensate changes its phase) indicate that the traditional theory of superconductivity known as the BCS theory [J. Bardeen, L. Cooper, J. Schrieffer “Theory of Superconductivity” Phys. Rev., 108, 1175-1204 (1957)] is not fully applicable to this range of superconductors.

It is clear that a new theory describing electron-electron interactions is required in order to explain the experimental data associated with HTS materials. Several such theories have been suggested to date but none have proven sufficient. Here, we propose a mechanism of electron-electron interaction based on a recently discovered New Quantum Interference Effect (NQIE)[Avto Tavkhelidze et. al. “Observation of Quantum Interference effect in Solids” J. Vac. Sci. Technol. B, Vol. 24, p. 1413, 2006].

NQIE will be described here in some detail in order to facilitate understanding of the present invention.

Consider potential energy box, shown in FIG. 1. It is well known from quantum mechanics that electrons placed inside the Potential Energy Box (PEB) will occupy discrete energy levels corresponding to separate quantum states. Energy levels formed according to Fermi statistics will fill the energy region up to the Fermi energy level. The Fermi level is independent of the dimensions and geometry of the PEB, except if one or more of the dimensions of the PEB becomes comparable to the wavelength of the de Broglie electron wave.

Consider now a modified PEB with specialized geometry, shown in FIG. 2. In order to simplify the problem, we will only consider electrons with wave vectors k=kₓ, k_{y}=k_{z}=0. Periodic indents are present on one wall of the modified PEB (MPEB). Electron waves reflected from the top and bottom of each indent interfere destructively, thereby canceling each other out and preventing reflection from the modified wall. This leads to the forbidding of some electron quantum states inside an MPEB of such geometry. Assuming the total number of electrons inside the MPEB remains the same, some electrons will therefore be forced to occupy higher energy levels. As a result, the Fermi energy level increases. Because the Fermi level of electrons in the MPEB is higher than that of electrons in the PEB and the total energy of electrons in the MPEB is higher than in the PEB, the electron gas in the MPEB can be regarded as an excited system or Super Degenerate Fermi Gas (SDFG).

The theory of quantum interference effects was first theorized in [Avto Tavkhelidze, Stuart Harbron “Influence of Surface Geometry on Metal Properties” U.S. Pat. No. 7,074,498. An increase in the Fermi level has been observed experimentally in solids by several groups [Avto Tavkhelidze et. al. “Observation of New Quantum Interference effect in Solids” J. Vac. Sci. Technol. B, Vol. 24, No. 3, May/June 2006, p. 1413].

At the core of the system described is the fact some energy levels are quantum mechanically forbidden due to the presence of indents. If some mechanism were to exist, external to the MPEB, allowing back previously forbidden energy levels, electrons would immediately occupy these energy levels and the Fermi level would decrease correspondingly. In other words, if allowed, the system will reduce its total energy and return back to the non-excited state shown in FIG. 1.

One of the possible mechanisms for re-allowing forbidden quantum states is quantum mechanical tunneling of electrons from the MPEB to an external object. If an electron can tunnel to another object positioned nearby, the electron is not forced to reflect back from the indented wall. Instead, the electron can simply leave the MPEB. Since it was impossibility of reflection back from the indented wall that was responsible for forbidding quantum states in the MPEB, the possibility of tunneling to external object reanimates previously forbidden quantum states [Avto Tavkhelidze “Method for Increasing of Tunneling Through Potential Barrier” U.S. Pat. No. 6,281,514]. Placing external objects in close proximity to the MPEB thus reduces the total energy of the electron gas inside the MPEB and evolves it from an excited state to a lower energy state.

The conclusion reached above can be expressed in terms of forces by stating that the placing an external object adjacent to a MPEB creates an attractive force between the MPEB and that object. The closer the external object is to the MPEB the greater the probability of tunneling (provided that there are enough empty quantum states available for electrons inside the external object) in response to the attractive force between them. This becomes obvious in light of the general principle that a system always tries to occupy the state with lowest possible energy.

The introduction of indents and their effect on electron distribution has also been noted in relation to thin films. Recent investigation of the electric properties of solid thin films (2D structures) show that, in the case where the thickness of the film is comparable with the electron de Broglie wavelength, thin films exhibit some principally new properties connected with wave nature of the electrons. This is relevant to HTS since it is known that HTS materials have a layered structure. For example YBa₂Cu₃O₇₋ₓ contains layers of CuOₓ separated by a layer containing Y atoms and a layer containing Ba atoms. Each layer can be regarded as a thin film or 2D structure.

### BRIEF SUMMARY OF THE INVENTION

In general terms the present invention concerns a superconducting tunnel junction comprising two films of material having an indented surface and separated by a distance sufficient to allow electrons to tunnel between them. The width and depth of the indents is such as to alter the electronic energy distribution in the films. The films each have an opposing plane surface parallel to the indented surface, and they have a thickness less than the electron mean free path in the film materials. In a further embodiment an insulator layer separates the films.

The present invention also concerns a method for promoting the formation of Cooper pairs which involves indenting a first film of material and a second film of material to alter the electronic energy distribution in each of them, placing the first film of material a distance from the second film of material, and allowing electrons to tunnel between said first film and said second film. The films each have an opposing plane surface parallel to the indented surface, and they each have a thickness less than the electron mean free path of said film materials.

The present invention also concerns a method of increasing the superconducting transition temperature of superconducting metals that involves introducing indents on the surface of a superconductor, such that the width and depth of the indents alter the electronic energy distribution in said superconductor.

The theory proposed as underlying the superconductive properties of the present invention is based on dividing HTS materials into 2D layers, each having properties connected with the wave nature of electrons. Interactions of these 2D layers are suggested to be the mechanism responsible for electron-electron attraction and creation of Cooper pairs.

In a preferred embodiment the depth of the indents is in the range of 5 to 10 nm.

In a further preferred embodiment the width of the indents is in the range of 50 to 200 nm.

In a preferred embodiment the thickness of the insulator layer in the superconducting tunnel junction is in the range of 1 to 3 nm.

In a further preferred embodiment the thickness of the films is less than the electron mean free path of a material comprising said films, and is typically in the range of 50 to 100 nm.

In further preferred embodiments the films are single crystal films or amorphous films.

In a further preferred embodiment of the superconducting tunnel junction the films comprises aluminum, preferably amorphous aluminum, and the insulator layer is aluminum oxide.

The present invention also comprises a method of fabricating the superconducting tunnel junction comprising depositing an aluminum film; forming a natural oxide layer on said film; and depositing a further aluminum film on said natural oxide layer.

### BRIEF DESCRIPTION OF THE SEVERAL VIEWS OF THE DRAWING

For a more complete explanation of the present invention and the technical advantages thereof, reference is now made to the following description and the accompanying drawing in which:

FIG. 1 is a Potential Energy Box (PEB) diagram showing that electrons placed inside it will occupy separate energy levels corresponding to separate quantum states;

FIG. 2 is a Modified Potential Energy Box (MPEB) having special geometry and corresponding energy levels;

FIG. 3 shows a first MPEB and a second MPEB in close proximity and the corresponding energy levels;

FIG. 4 shows the atomic structure of YBa₂Cu₃O₇₋ₓ; and

FIG. 5 shows a superconductor embodiment of the present invention comprising a tunnel junction between two thin films having indented surfaces.

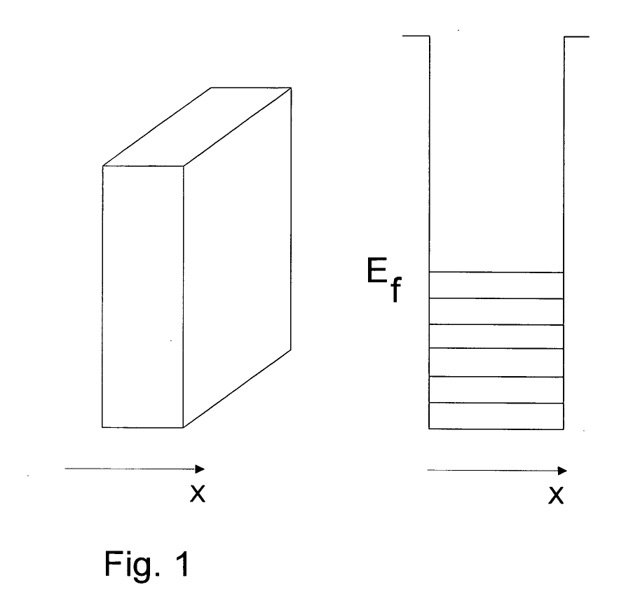

### DETAILED DESCRIPTION OF THE INVENTION

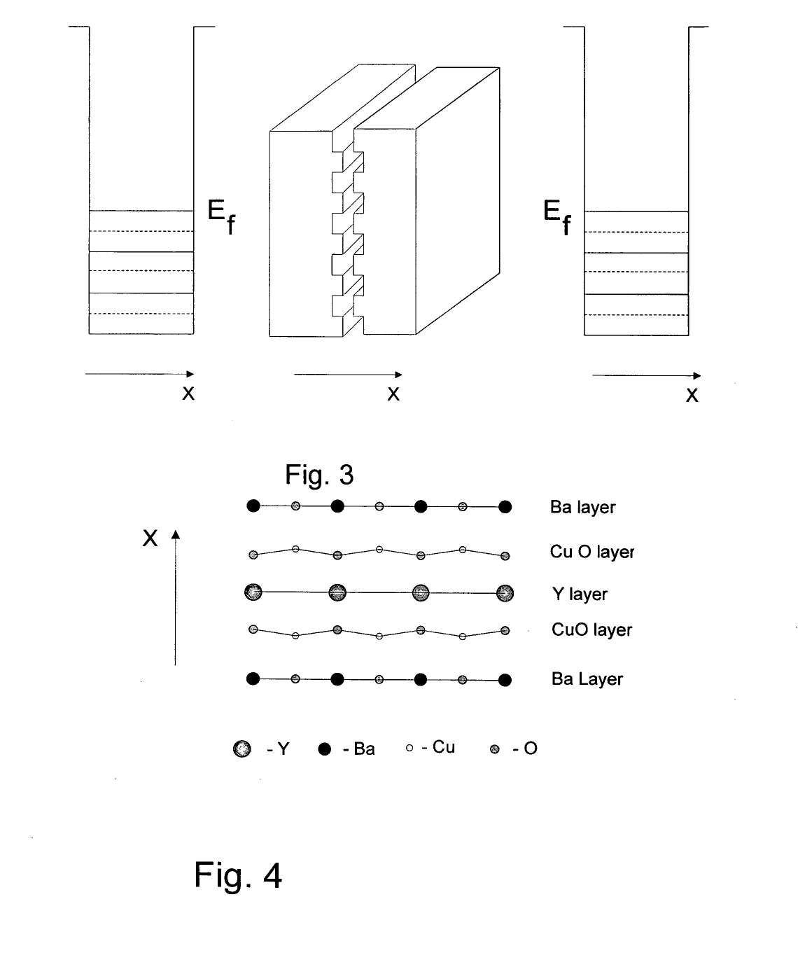

Embodiments of the present invention and their technical advantages may be better understood by referring to FIGS. 3-5. [31] The mechanism proposed as responsible for the present invention is best explained by referring to FIG. 3. Referring now to FIG. 3, which shows a first MPEB and a second MPEB as the external object referred to in the earlier discussion. We now have a composite system containing two excited subsystems of electrons in SDFG. It is clear that when the two MPEBs come close to each other, previously forbidden energy levels (shown as dotted lines in FIG. 3) start to reanimate in both due to the possibility of tunneling to the neighboring MPEB. Both MPEBs will attract each other with an attractive force that increases as the distance between the MPEBs decreases. Further, it is clear that it is the electrons from the two subsystems of SDFGs that attract each other. This type of attraction can be regarded as the mechanism responsible for the creation of Cooper pairs. As Cooper has proven, electron pairs in a degenerate Fermi gas will form even in the case of an infinitely small force of attraction between electrons.

Cooper pairs contain two electrons with opposite momentum and spin to each other. Let us now look at the possibility of forming such a pair in the system shown in FIG. 3 comprising two MPEBs. In a PEB, each energy level is occupied by two electrons having opposite spins. Both electrons have the same energy but because of their different spins they are in different quantum states. At first, one might argue that an energy state reanimated in one MPEB should also contain two electrons having opposite spins and similarly for energy states in the second adjacent MPEB. However, a more detailed analysis shows that this cannot be true. The mechanism of reanimation of the quantum state is such that tunneling has to be allowed from one MPEB to another MPEB. In order for a tunneling event to occur the quantum state receiving the electron must be empty (this is a general requirement of Fermi statistics). For example, if electron with k↑ in one MPEB is to tunnel to the second MPEB then the quantum state k↑ must be empty in the receiving MPEB. The same is true for an electron having—k↓.

It follows from the above that the quantum states in the two MPEBs must be correlated in order to allow tunneling. One of the possible correlations is that electron k↑ exists in the first MPEB and does not exist in the other whereas electron—k↓ exists in the second MPEB and does not exist in the first. Now, this description corresponds to that of Cooper pairs. It is clear then that in the case of two similar MPEBs placed close to each other a correlated quantum state (we can not ascribe the correlated quantum state to one of the MPEBs because of symmetry) occupied by a Cooper pair could be reanimated to reduce the total energy of the system containing two subsystems of electrons or two SDFGs.

The discussion so far has focused on one particular quantum state. In reality, many correlated quantum states will appear to reduce the total energy of the system. Cooper pairs with zero total momentum will exist as already described; Cooper pairs with non-zero momentum will also be created from electrons with different momentum in the two MPEBs and such a pair carries electric charge without dissipation.

We have so far discussed the new mechanism responsible for creating the Cooper pairs in a system containing two subsystems of SDFG. The theory outlined must now be shown to be viable for HTS ceramics. This can be shown by considering the atomic structure of YBa₂Cu₃O₇₋ₓ, shown in FIG. 4. The structure can be divided into a number of 2D layers comprising layers of Y and Ba atoms separated by layers of CuOₓ. The CuOₓ layers merit further consideration because of their unusual structure. In these layers, oxygen atoms are slightly shifted up and down periodically relative the common plane of the CuOₓ molecules. That periodic shift creates geometry similar to periodic indents on the wall of the MPEB described earlier.

Now let us divide the YBa₂Cu₃O₇₋ₓ crystal into layers of Ba and Y separated by double layers of CuOₓ. The geometry becomes similar to two MPEBs both containing Ba atoms and both having indented structure on the surface formed by CuOₓ layers. The “insulating” Y layer serves as a potential barrier between the two “conductive” Ba layers. According to the theory discussed above, two electrons in neighboring Ba layers can form Cooper pairs to reanimate some quantum states in the Ba layers and reduce the total energy of the system.

The main achievement of the proposed mechanism of attraction between electrons is that it explains extremely low value of order parameters in YBa₂Cu₃O₇₋ₓ and other HTS superconducting materials. Electron pairs are concentrated within a few atomic layers and consequently the order parameter should be about 10 A which is in good agreement with experimental data.

Another advantage of the mechanism is that it explains the role of CuOₓ layers in forming HTS. CuOₓ is seemingly the only common component of all HTS materials. The fact that the Fermi energy is much less in cuprates as compared to other metal compounds implies that the de Broglie wave of a free quasiparticle in cuprates is much more than in metals. The wave vector varies with Fermi energy approximately as k_{f}˜(E_{f})^{1/2} where k_{f} is the wave vector of an electron at the Fermi surface and E_{f} is the Fermi energy. The effective E_{f} in cuprates is believed to be 0.3 eV, which is approximately one order less than it is in traditional superconductive metals. Consequently, the wave vector should be 3-4 times less and the de Broglie wave 3-4 times longer than it is in traditional superconductors. The relatively large wavelength of the electron allows it to tunnel through larger distances of the order of many CuOₓ layers. The possibility of such tunneling increases the quantum mechanical coupling of the layers and reduces the total energy of the system considerably via the mechanism described.

The model is also in agreement with the experimental finding that in HTS the pseudo gap in the energy spectrum does not depend on temperature and exists above T_{c}.

The mechanism can furthermore be applied to conventional superconducting materials such as Pb and Nb. In metals, the electron gas is degenerate, meaning that the kinetic energy of an electron at the Fermi energy is much more than k_{B}T, where K_{B} is Boltsman's constant and T is absolute temperature. Because free electrons are much hotter than would be the case if they thermally equilibrated with their environment, electrons tend to reduce their energy. One of the possible ways of reducing the energy of the electron gas is through the formation of Cooper pairs via the exchange of phonons. The more degenerate the electron gas, the greater the ‘pressure’ to reduce the energy.

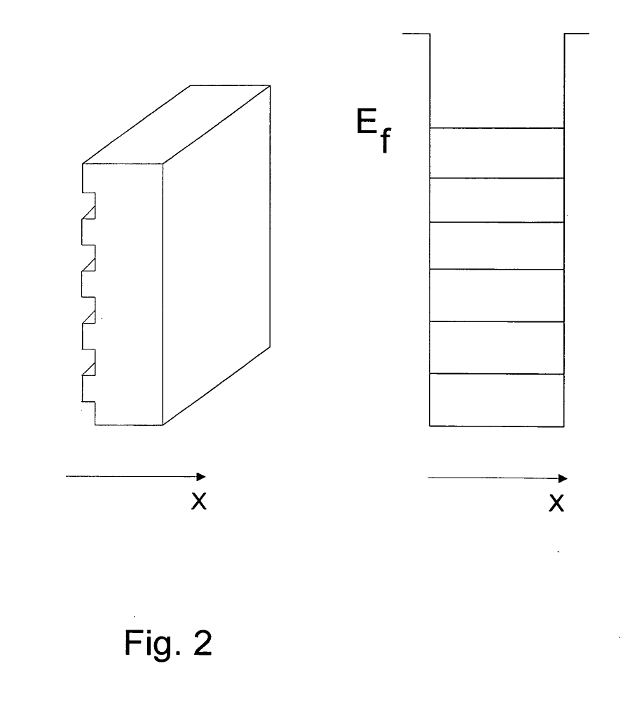

Consider Nb or Pb having an indented surface as shown in FIG. 2. NQIE dictates that some energy levels will become forbidden and the Fermi level will increase. Consequently, the electron gas degeneration level will rise and the electron gas will be further forced to reduce its energy. Like all other ordinary superconductors, Nb or Pb containing a super degenerate electron gas will form Cooper pairs at low temperatures. It is expected that Nb containing a super degenerated electron gas will have a higher superconducting transition temperature, T_{c}, in comparison to a plain Nb film. Increasing of the T_{c} will occur because the super degenerated electron gas is forced to reduce its energy and thus the formation of Cooper pairs will start at higher temperatures. The same is true for Pb or any other superconductive metal.

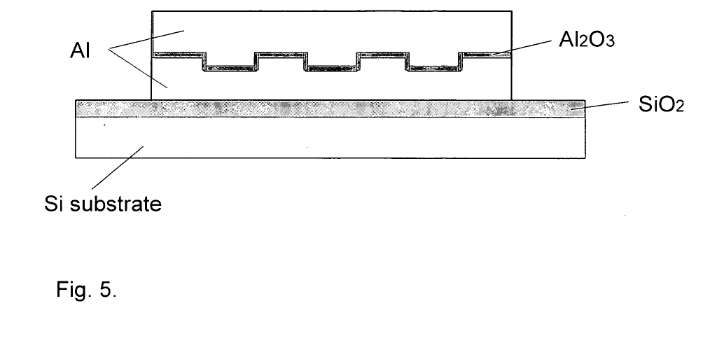

One of the simplest ways to exploit the proposed mechanism of superconductivity seems to be in a tunnel junction between two thin films having indented surfaces. Such a structure is shown in FIG. 5. The depth of the indents is 5-10 nm and the width of the indents 50-200 nm. The most suitable material for the tunnel junction is Al because it forms a natural insulating oxide Al₂O₃. The desired thickness of the natural oxide is 10-30 Å.

The natural oxide of Al is usually formed in situ after deposition of the Al film. Dry oxygen is allowed into the deposition chamber under low pressure during fixed time period. Afterwards, the chamber is pumped out and another film of Al is deposited on the top. The thickness of both Al films must be less than the electron mean free path in Al. This is a fundamental requirement because only under these conditions will the electron have wave properties inside the film.

The electron mean path depends on the structure of the film. In a particularly preferred embodiment of the present invention single crystal films used. Such films are ideal for this purpose because the electron has its maximum mean free path in them. However, single crystal films are difficult to realize and rather impractical. The next suitable candidate is an amorphous film. An amorphous Al film can be made using fast thermal evaporation of the Al and deposition on a cold substrate. Thickness of the films should be in the range of 50-100 nm and roughness of the film should be less than 10 Å. In order to observe superconductive components of the current in such a tunnel junction its resistance and I-V characteristic should be measured precisely.

In a further embodiment of the present invention thin films are formed of other conventional superconductors, such as Pb and Nb. The superconducting transition temperature of these traditional superconductors is increased by way of introducing indents on their surface. The extent to which the transition temperature is increased depends on the increase of the Fermi level which depends in turn on strength of NSQIE, which itself depends on material structure and surface roughness.

Other applications of the new mechanism of superconductivity will be in high current devices including superconductive energy transition lines, superconductive magnets, Superconductive Quantum Interference Devices SQUID's, low noise photon detectors and other devices based on the Josephson Effect. The new mechanism of superconductivity could also be used for the reduction (or even elimination) of contact resistance in various type of high current devices such as thermoelectric and thermotunnel refrigerators and power generators.

Although the description above contains many specificities, these should not be construed as limiting the scope of the present invention but as merely providing illustrations of some of the presently preferred embodiments of the invention. Thus the scope of the present invention should be determined by the appended claims and their legal equivalents, rather than by the examples given.

1. A superconducting tunnel junction comprising a first film of material separated by a distance sufficient to allow electrons to tunnel between said first film and a second film; characterized in that said films have an indented surface wherein the width and depth of said indents is such as to alter the electronic energy distribution in said material, said first and said second film each have an opposing plane surface parallel to said indented surface, said first and said second film have a thickness less than the electron mean free path of said film materials.

2. The superconducting tunnel junction of claim 1, in which a width of said indents is in the range of 50 to 200 nm.

3. The superconducting tunnel junction of claim 1, in which a depth of said indents is in the range of 5 to 10 nm.

4. The superconducting tunnel junction of claim 1 wherein said distance is in the range 1 to 3 nm.

5. The superconducting tunnel junction of claim 1 additionally comprising an insulator layer between and in contact with said first and second film.

6. The superconducting tunnel junction of claim 1 in which a thickness of said films is in the range of 50 to 100 nm.

7. The superconducting tunnel junction of claim 1 in which said material is selected from the group consisting of: single crystal, amorphous material, aluminum, superconductor metal, lead, and niobium.

8. The superconducting tunnel junction of claim 7 in which said aluminum comprises amorphous Al.

9. The superconducting tunnel junction of claim 1 in which said insulator layer comprises aluminum oxide.

10. A method for promoting the formation of Cooper pairs comprising the steps:
(a) indenting a first film of material and a second film of material thereby altering an electronic energy distribution in each of said first and said second film wherein said first and said second film each having an opposing plane surface parallel to said indented surface, said first and said second film each having a thickness less than the electron mean free path of said film materials;
(b) placing said first film of material a distance from said second film of material; and
(c) allowing electrons to tunnel between said first film and said second film.

11. The method of claim 10, in which a width of said indents is in the range of 50 to 200 nm.

12. The method of claim 10, in which a depth of said indents is in the range of 5 to 10 nm.

13. The method of claim 10 wherein said distance is in the range 1 to 3 nm.

14. The method of claim 10 additionally comprising the step of placing an insulator layer between and in contact with said first and second film.

15. The method of claim 10 in which a thickness of said films is in the range of 50 to 100 nm.

16. The method of claim 10 in which said material is selected from the group consisting of: single crystal, amorphous material, aluminum, superconductor metal, lead, and niobium.

17. A method of increasing the superconducting transition temperature of superconducting metals comprising introducing indents on the surface of the superconductor, wherein the width and depth of said indents is such as to alter the electronic energy distribution in said superconductor.

18. The method of claim 17 in which a width of said indents is in the range of 50 to 200 nm.

19. The method of claim 17 in which a depth of said indents is in the range of 5 to 10 nm.

20. The method of claim 17 in which a thickness of said films is in the range of 50 to 100 nm.
